(19) United States
(12) Patent Application Publication
(10) Pub. No.: US 2014/0084255 A1
(43) Pub. Date: Mar. 27, 2014

(54) Organic Light-Emitting Diode Using Bandgap Matching Dye as Co-Host

(71) Applicant: NATIONAL TSING HUA UNIVERSITY, Hsinchu (TW)

(72) Inventors: Jwo-Huei Jou, Hsinchu (TW); Yung-Cheng Jou, Hsinchu (TW)

(73) Assignee: National Tsing Hua University, Hsinchu (TW)

(21) Appl. No.: 13/674,011

(22) Filed: Nov. 10, 2012

(30) Foreign Application Priority Data
Sep. 21, 2012 (TW) 101134690

(51) Int. Cl. H01L 51/50

(52) U.S. Cl. CPC H01L 51/5012
USPC 257/40

(57) ABSTRACT

The present invention relates to an organic light-emitting diode using an bandgap matching dye as a co-host, comprising: a first conductive layer, a hole injection layer, a hole transport layer, a host light-emitting layer, a first dye, a second dye, an electronic transport layer, an electronic injection layer, and a second conductive layer; wherein the host energy gap of the host light-emitting layer is greater than the energy gap of the first dye, and the energy gap of the first dye is greater than the energy gap of the second dye; therefore the first dye can be a co-host light-emitting layer opposite to the host light-emitting layer, and the energy of the first dye can be effectively conducted to the second dye, such that the luminous efficiency of the light emitted by the second dye through the host light-emitting layer is largely enhanced.

### BACKGROUND OF THE INVENTION

1. Field of the Invention

The present invention relates to a high-efficiency organic light-emitting diode (OLED), and more particularly to an organic light-emitting diode using bandgap matching dye as co-host.

2. Description of the Prior Art

An organic light emitting diode (OLED) was invented by C. W. Tang and S. A. VanSlyk et al. of Eastman Kodak Company in 1987 and manufactured by a vacuum evaporation method. A hole transporting material and an electron transporting material (such as Alq₃) are respectively deposited on a transparent indium tin oxide (abbreviated as ITO) glass, and then a metal electrode is vapor-deposited thereon to form the self-luminescent OLED apparatus. Due to high brightness, fast response speed, light weight, compactness, true color, no difference in viewing angles, no need of liquid crystal display (LCD) type backlight plates as well as a saving in light sources and low power consumption, it has become a new generation display.

In addition to light-emitting material layers, the conventional OLED device is often added to other intermediate layers, such as an electron transport layer and a hole transport layer, so as to enhance the efficiency of the OLED device. Referring to FIG. 1, which is a structural drawing of a conventional OLED device. As shown in FIG. 1, the conventional OLED device 1′ includes a cathode 11′, an electron injection layer 12′, an electron transport layer 13′, a first light-emitting material layer 14′, a second light-emitting material layer 15′, a hole transport layer 16′, a hole injection layer 17′, and an anode 18′.

The above-mentioned conventional OLED device 1′ is an OLED device with high efficiency. However, referring to FIG. 2, which is a curve diagram of the luminous efficiency of the conventional OLED device 1′. As shown in FIG. 2, when the brightness of the conventional OLED device 1′ is higher than 3500 cd/m², the luminous efficiency of the conventional OLED device 1′ is decreased rapidly. Such a phenomenon is called an Efficiency Roll-Off phenomenon of the conventional OLED device 1′.

According to the conventional OLED device has the drawback of the Efficiency Roll-Off, OLED manufacturers have made great efforts to make inventive research thereon and eventually provided an OLED device with mixed light-emitting layer. Please refer to FIG. 3, which illustrates a structural drawing of an OLED device with a mixed light-emitting layer. As shown in FIG. 3, the OLED device 1″ with the mixed light-emitting layer includes: a first conductive layer 11″, a hole injection layer 12″, a hole transport layer 13″. A first light-emitting layer 14″, a second light-emitting layer 15″, an electron transport layer 16″, an electron injection layer 17″, a second conductive layer 18″, and a third light-emitting layer 19″, wherein the first conductive layer 11″ is an Indium Tin Oxid (ITO), used as an anode of the OLED device 1″. The hole injection layer 12″, the hole transport layer 13″, the first light-emitting layer 14″, the third light-emitting layer 19″, the second light-emitting layer 15″, the electron transport layer 16″, the electron injection layer 17″, and the second conductive layer 18″ are sequentially formed on the ITO substrate.

In the aforesaid OLED device 1″ with the mixed light-emitting layer, the third light-emitting layer 19″ is formed by mixing part of the first light-emitting layer 14″ and part of the second light-emitting layer 15″, and the thickness of the third light-emitting layer 19″ should be less than 10 nm. Please refer to FIG. 4, which illustrates a curve diagram of the luminous efficiency of the OLED device with the mixed light-emitting layer. As shown in FIG. 4, the solid curve with solid triangles represents the luminous efficiency data plot of the prior art OLED device; the dashed curve with hollow circles represents the luminous efficiency data plot of the OLED device 1″ with the mixed light-emitting layer. Wherein when the brightness of the OLED devices exceed 3500 cd/m², the solid curve and the dashed curve begin to decline. However, when the brightness is about 10000 cd/m², the hollow circles on the dashed curve are higher than the solid triangles on the solid curve. Thus, through the curves shown in FIG. 4, it can understand that the Efficiency Roll-off phenomenon in the high-brightness area of the OLED device 1″ with the mixed light-emitting layer is improved greatly compared to the prior art OLED device.

Accordingly, through above descriptions, it is able to know that the OLED device with the mixed light-emitting layer may improved the drawback of the efficiency roll-off existing in the prior art OLED devices. However, the brightness and the luminous efficiency showed by the OLED device with the mixed light-emitting layer are still inadequate for making the OLED devices with the mixed light-emitting layer to replace the LED devices being used as the lighting devices and display devices.

Thus, in view of the conventional OLED device and the OLED devices with the mixed light-emitting layer still have shortcomings and drawbacks, the inventor of the present application has made great efforts to make inventive research thereon and eventually provided an organic light-emitting diode using bandgap matching dye as co-host.

### SUMMARY OF THE INVENTION

The primary objective of the present invention is to provide an organic light-emitting diode (OLED) using bandgap matching dye as co-host, in this OLED, the host light-emitting layer of the organic light-emitting diode is doped with a first dye and a second dye, wherein the host energy gap of the host light-emitting layer is greater than the energy gap of the first dye, and the energy gap of the first dye is greater than the energy gap of the second dye; therefore the first dye can be a co-host light-emitting layer opposite to the host light-emitting layer, and the energy of the first dye can be effectively conducted to the second dye, such that the luminous efficiency of the light emitted by the second dye through the host light-emitting layer is largely enhanced.

Accordingly, to achieve the primary objective of the present invention, the inventor of the present invention provides an organic light-emitting diode using bandgap matching dye as co-host, comprising:

a first conductive layer;

a hole injection layer, being formed on the first conductive layer;

a hole transport layer, being formed on the hole injection layer;

a host light-emitting layer, being formed on the hole transport layer and having a host energy gap;

a first dye, being doped in the host light-emitting layer;

a second dye, being doped in the host light-emitting layer;

an electron transport layer, being formed on the host light-emitting layer;

an electron injection layer, being formed on the electron transport layer; and

a second conductive layer, being formed on the electron injection layer;

wherein the host energy gap of the host light-emitting layer is greater than the energy gap of the first dye, and the energy gap of the first dye is greater than the energy gap of the second dye; therefore the first dye can be a co-host light-emitting layer opposite to the host light-emitting layer, and the energy of the first dye can be effectively conducted to the second dye, such that the luminous efficiency of the light emitted by the second dye through the host light-emitting layer is largely enhanced.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 is a structural drawing of a conventional OLED device;

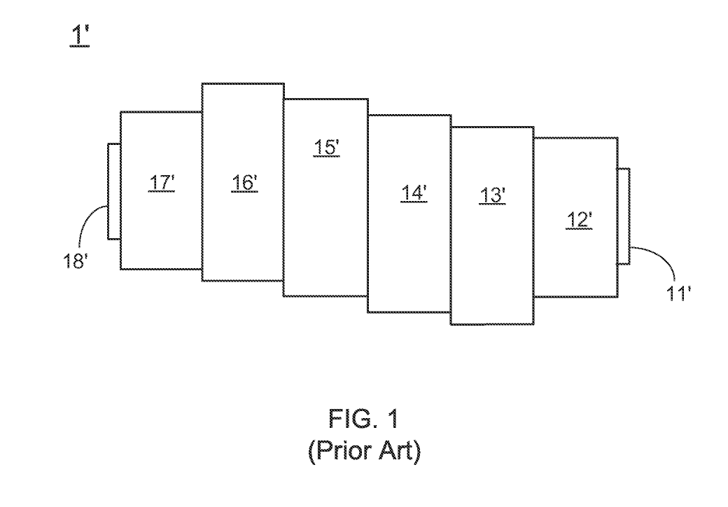

FIG. 2 is a curve diagram of the luminous efficiency of the conventional OLED device;

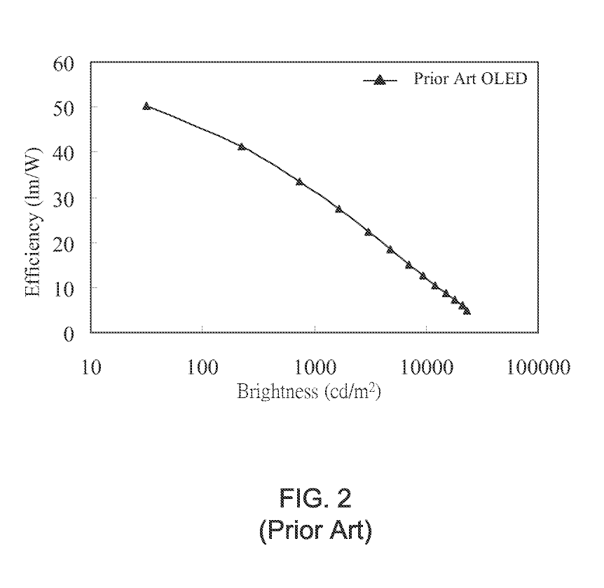

FIG. 3 is a structural drawing of an OLED device with a mixed light-emitting layer;

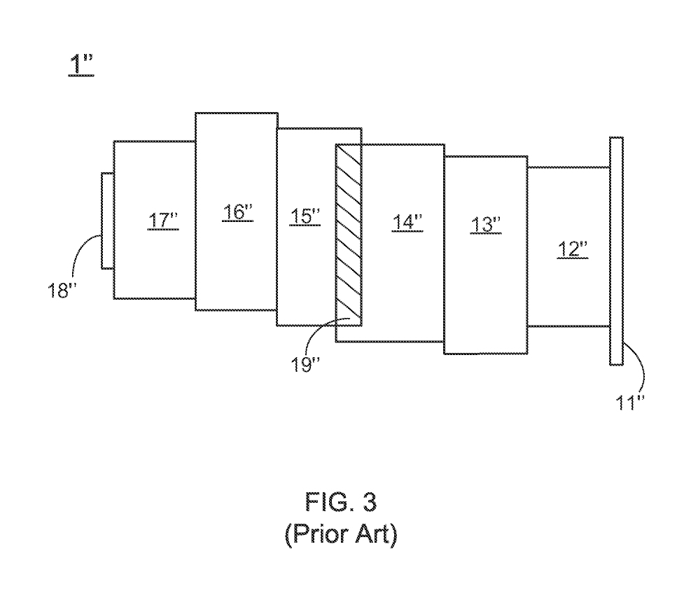

FIG. 4 is a curve diagram of the luminous efficiency of the OLED device with the mixed light-emitting layer;

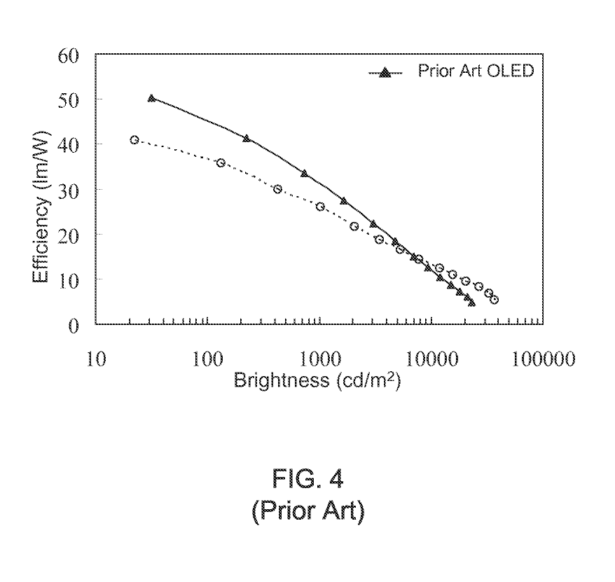

FIG. 5 is a structural drawing of an organic light-emitting diode using bandgap-matching dye as co-host according to the present invention;

FIG. 6 is an energy band view of the organic light-emitting diode using bandgap-matching dye as co-host according to the present invention;

FIG. 7A is an energy band view of an organic light-emitting diode doped with a second dye;

FIG. 7B is an energy band view of an organic light-emitting diode doped with a first dye and a second dye;

FIG. 8 is a curve plot of the current density of the organic light-emitting diode;

FIG. 9 is a curve plot of the luminance of the organic light-emitting diode;

FIG. 10 is a curve plot of the power efficiency of the organic light-emitting diode;

FIG. 11A is an energy band view of an organic light-emitting diode doped with a second dye;

FIG. 11B is an energy band view of an organic light-emitting diode doped with a first dye and a second dye;

FIG. 12 is a curve plot of the current density of the organic light-emitting diode;

FIG. 13 is a curve plot of the luminance of the organic light-emitting diode;

FIG. 14 is a curve plot of the power efficiency of the organic light-emitting diode;

FIG. 15A is an energy band view of an organic light-emitting diode doped with a second dye;

FIG. 15B is an energy band view of an organic light-emitting diode doped with a first dye and a second dye;

FIG. 16 is a curve plot of the current density of the organic light-emitting diode;

FIG. 17 is a curve plot of the luminance of the organic light-emitting diode;

FIG. 18 is a curve plot of the power efficiency of the organic light-emitting diode;

FIG. 19A is an energy band view of an organic light-emitting diode doped with a second dye;

FIG. 19B is an energy band view of an organic light-emitting diode doped with a first dye and a second dye;

FIG. 20 is a curve plot of the current density of the organic light-emitting diode;

FIG. 21 is a curve plot of the luminance of the organic light-emitting diode; and

FIG. 22 is a curve plot of the power efficiency of the organic light-emitting diode.

### DETAILED DESCRIPTION OF THE PREFERRED EMBODIMENTS

To more clearly describe an organic light-emitting diode using bandgap matching dye as co-host according to the present invention, embodiments of the present invention will be described in detail with reference to the attached drawings hereinafter.

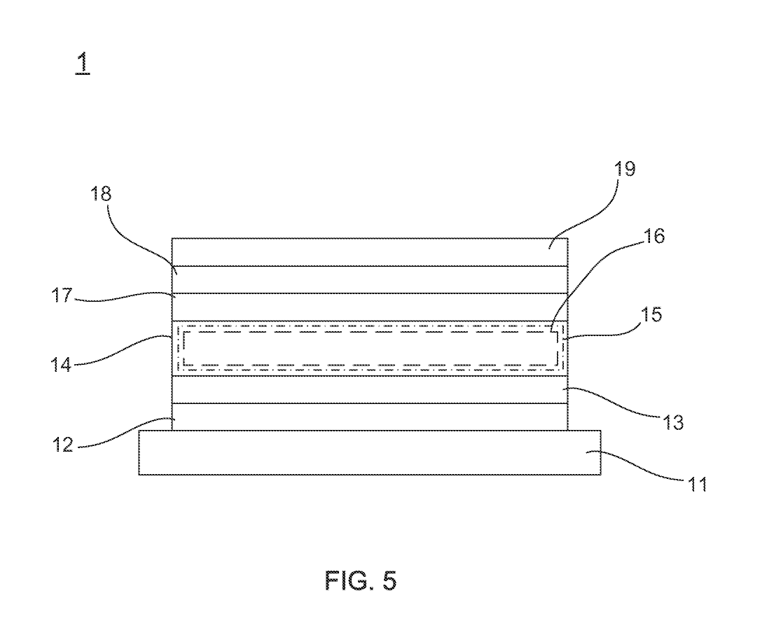

Referring to FIG. 5, it illustrates a structural drawing of the organic light-emitting diode using bandgap-matching dye as co-host according to the present invention. As shown in FIG. 5, the organic light-emitting diode 1 of the present invention includes: a first conductive layer 11, a hole injection layer 12, a hole transport layer 13, a host light-emitting layer 14, a first dye 15, an electron transport layer 17, an electron injection layer 18, and a second conductive layer 19.

In this organic light-emitting diode (OLED) 1, the first conductive layer 11 is an indium tin oxide (ITO) for being as an anode. The hole injection layer 12 is formed on the first conductive layer 11, and the hole transport layer 13 is formed on the hole injection layer 12. Sequentially, the host light-emitting layer 14 is formed on the hole transport layer 13 and has a host energy gap, and both the first dye 15 and the second dye 16 are doped in the host light-emitting layer 14. Moreover, electron transport layer 17 is formed on the host light-emitting layer 14, and the electron injection layer 18 is formed on the electron transport layer 17. Eventually, the second conductive layer 19 is formed on the electron injection layer 18, wherein the material of the second conductive layer 19 is aluminum, used as a cathode.

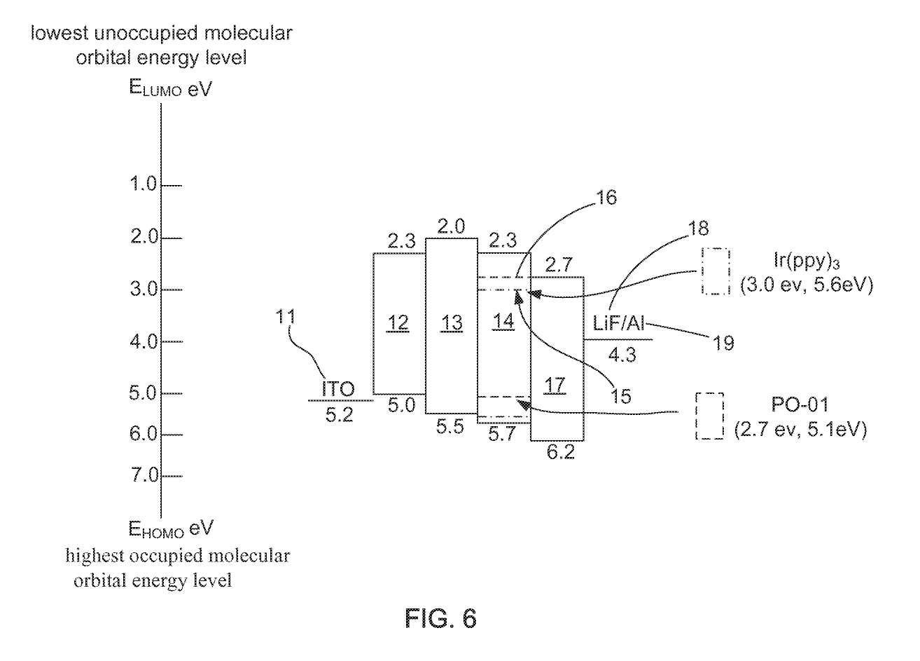

Continuously referring to FIG. 5, and please refer to FIG. 6 simultaneously, there is shown an energy band view of the organic light-emitting diode using bandgap-matching dye as co-host according to the present invention. In FIG. 6, the hole injection layer 12 is poly(3,4-ethylene-dioxythiophene):poly-(styrenesulfonate) (PEDOT:PSS), the material of the hole transport layer is (1,1-bis{4-[di(p-tolyl)amino]-phenyl}cyclohexane) (TAPC), the material of the host light-emitting layer is 4,4′,4″-Tri(9-carbazoyl)triphenylamine (TCTA), the first dye is tris(2-phenylpyridine)iridium (Ir(ppy)₃), the second dye is iridium(III)bis(4-phenylthieno[3,2-c]pyridinato-N,C2) acetylacetonate (PO-01), the material of the electron transport layer being 1,3,5-tris(N-phenylbenzimidazol-2-yl)benzene (TPBi), and the material of the electron injection layer is LiF.

Herein, it needs to noted that, the materials of PEDOT:PSS, TAPC, TCTA, Ir(ppy)₃, PO-01, TPBi, and LiF are exemplarily used for making the hole injection layer 12, the hole transport layer 13, the host light-emitting layer 14, the first dye 15, the second dye 16, the electron transport layer 17, and the electron injection layer 18, but these materials does not intended to limit the OLED 1 of the present invention. As shown in FIG. 6, the lowest unoccupied molecular orbital energy level of host E_{LUMO} and the high occupied molecular orbital energy level of host E_{HOMO} of the host light-emitting layer (TCTA) 14 are 2.3 eV and 5.7 eV, respectively. The E_{LUMO} and E_{HOMO} of the first dye (Ir(ppy)₃) 15 are 3.0 eV and 5.6 eV, and the E_{LUMO} and E_{HOMO} of the second dye (PO-01) 16 are 2.7 eV and 5.1 eV.

So that, through FIG. 6, it can easily understand that the host energy gap of the host light-emitting layer 14 is greater than the energy gap of the first dye 15, and the energy gap of the first dye 15 is greater than the energy gap of the second dye 16; therefore the first dye 15 can be a co-host light-emitting layer opposite to the host light-emitting layer 14, and the energy of the first dye 15 can be effectively conducted to the second dye 16, such that the luminous efficiency of the light emitted by the second dye through the host light-emitting layer 14 is largely enhanced.

Moreover, in this OLED 1 of the present invention, the first dye 15 (Ir(ppy)₃) and the second dye 16 (PO-01) can also be doped into the host light-emitting layer 14 of TPBi (1,3,5-tris(N-phenylbenzimidazol-2-yl)benzene) and CBP (4,4′-Bis(9H-carbazol-9-yl)biphenyl), the host light-emitting layer 14 of TPBi or CBP can also make the first dye 15 be a co-host light-emitting layer for facilitating the energy of the first dye 15 can be effectively conducted to the second dye 16, so as to increase the luminous efficiency of the light emitted by the second dye through the host light-emitting layer 14.

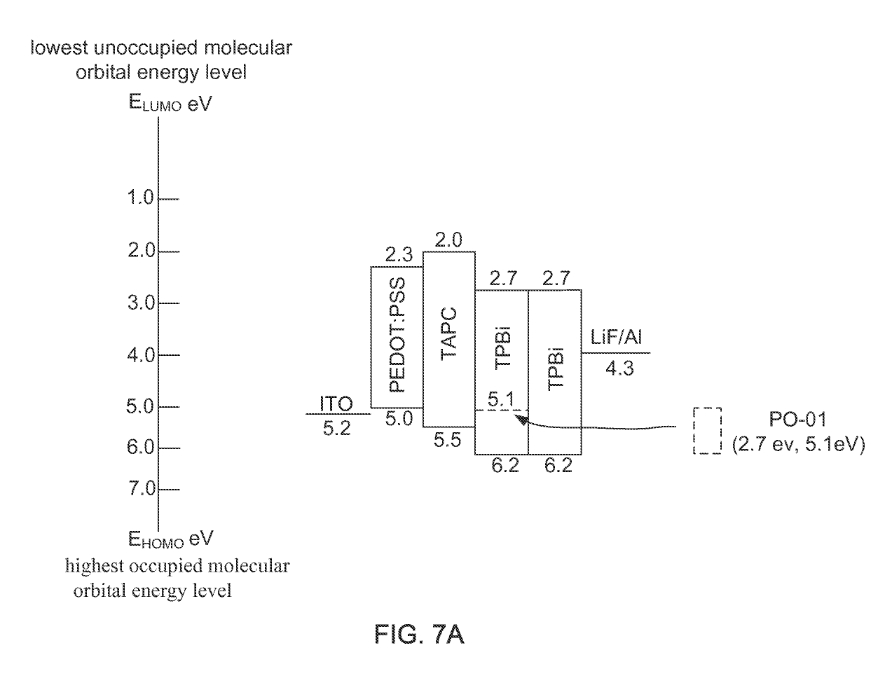

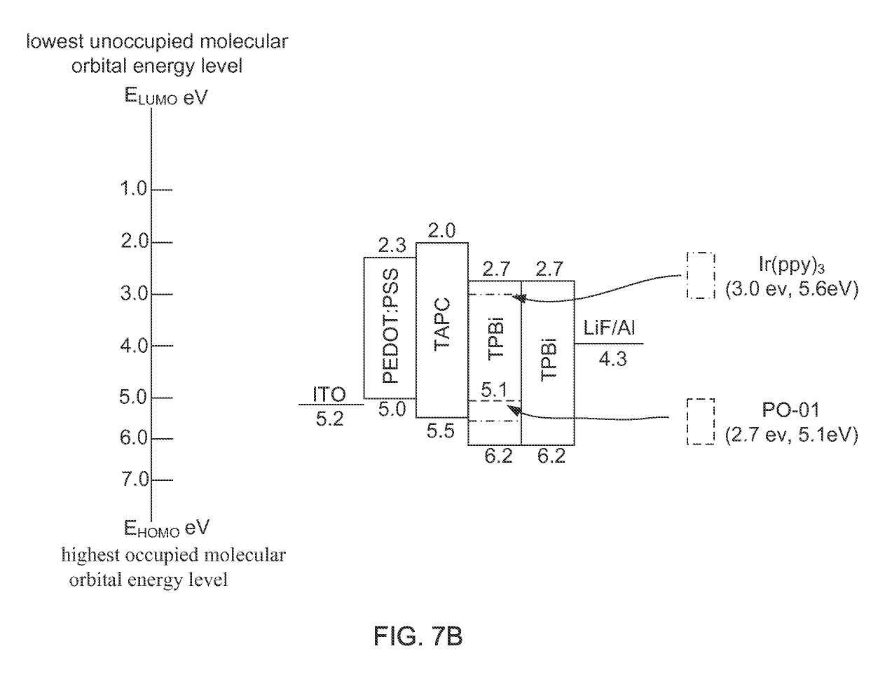

Thus, through the descriptions, the framework and feature of the organic light-emitting diode (OLED) 1 using bandgap matching dye as co-host of the present invention has been completely introduced, and then the practicability of this OLED 1 will be next proven by experiment data and results. Referring to FIG. 7A, it shows an energy band view of an organic light-emitting diode doped with a second dye; moreover, please simultaneously refer to FIG. 7B, it shows an energy band view of another organic light-emitting diode doped with a first dye and a second dye. The OLED of FIG. 7B is an experiment OLED device and the OLED of FIG. 7A is a control OLED device. As shown in FIG. 7A and FIG. 7B, the materials of PEDOT:PSS, TAPC, TCTA, PO-01, TPBi, and LiF are used for making the hole injection layer 12, the hole transport layer 13, the host light-emitting layer 14, the second dye 16, the electron transport layer 17, and the electron injection layer 18 of the experiment OLED and the control OLED; and furthermore, the Ir(ppy)₃ is used for making the first dye 15 of the experiment OLED in FIG. 7B.

Inheriting to above descriptions, the weight percentage (wt %) of second dye (PO-01) in the control OLED of FIG. 7A is 15 wt %; and oppositely, the weight percentage of second dye (PO-01) in the experiment OLED of FIG. 7B is ranged from 5 wt % to 15 wt %, and the best weight percentage of second dye (PO-01) in the experiment OLED is 5.8 wt %. In addition, the weight percentage of first dye (Ir(ppy)₃) in the experiment OLED of FIG. 7B is ranged from 5 wt % to 15 wt %, and the best weight percentage of first dye (Ir(ppy)₃) in the experiment OLED is 10 wt %.

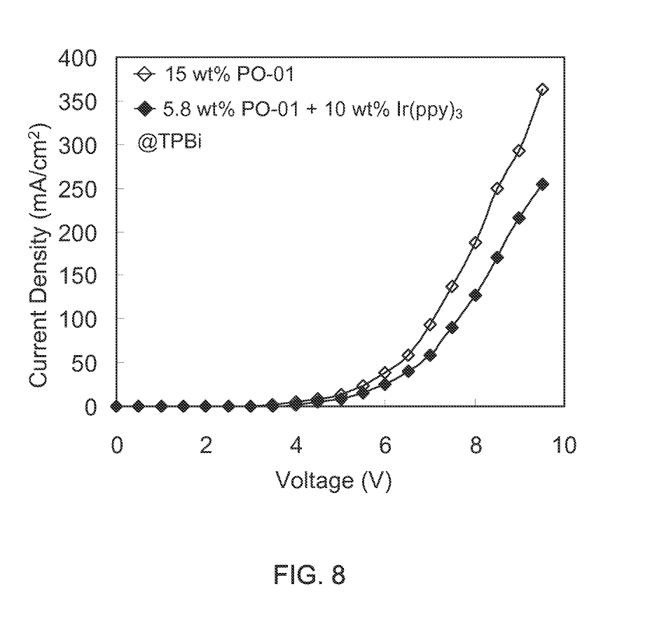

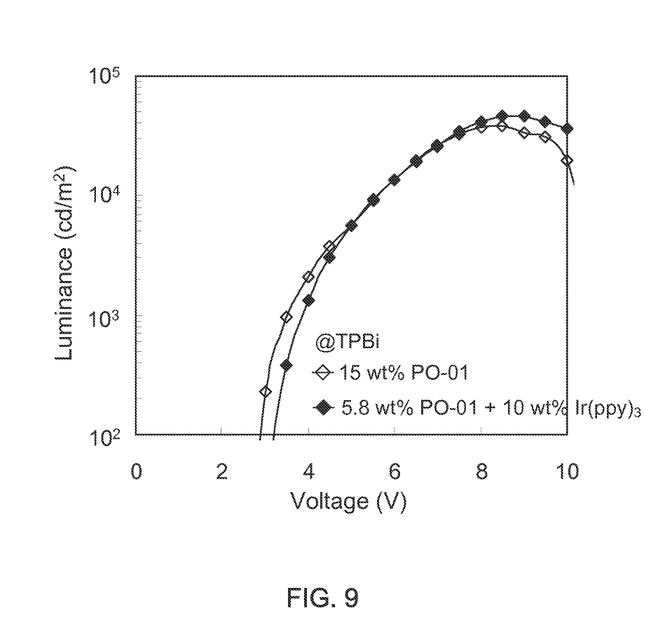

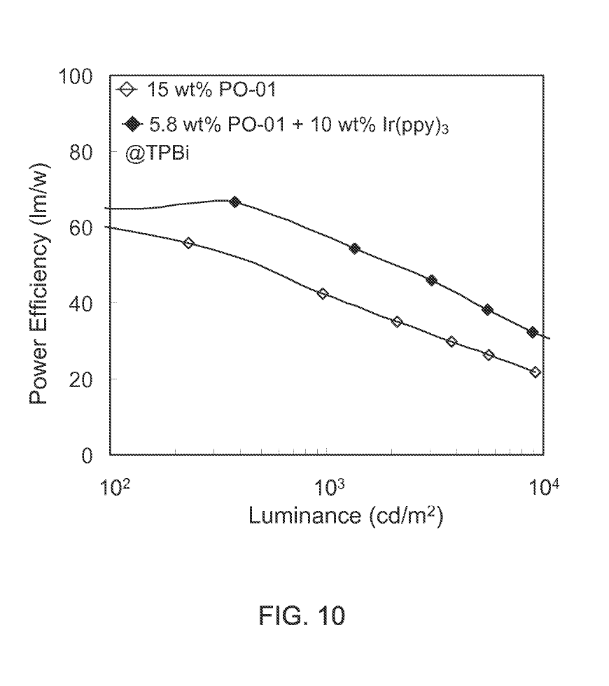

Please continuously refer to FIG. 8, FIG. 9 and FIG. 10, there are shown curve plots for the current density, the luminance and the power efficiency of two organic light-emitting diodes, respectively. In FIG. 8, the data points of hollow diamond represent the current density measured from the control OLED of FIG. 7A, and the data points of solid diamond represent the current density measured from the experiment OLED of FIG. 7B. As shown in FIG. 8, because doping concentration effect is induced by the first dye (Ir(ppy)₃) and the second dye (PO-01) in the experiment OLED of FIG. 7B, the current density curve constructed by the solid diamond data points is obviously lower than the current density curve constructed by the hollow diamond data points.

Besides, in FIG. 8, the data points of hollow diamond represent the luminance measured from the control OLED of FIG. 7A, and the data points of solid diamond represent the luminance measured from the experiment OLED of FIG. 7B. As shown in FIG. 9, there is no evident discrepancy between the luminance data of FIG. 7B and the luminance data of FIG. 7A. Furthermore, in FIG. 10, the data points of hollow diamond represent the power efficiency measured from the control OLED of FIG. 7A, and the data points of solid diamond represent the power efficiency measured from the experiment OLED of FIG. 7B. As shown in FIG. 10, since the first dye (Ir(ppy)₃) becomes a co-host layer for the second dye (PO-01) in the host light-emitting layer (TPBi), the luminous efficiency of the light emitted by the second dye (PO-01) through the host light-emitting layer (TPBi) is enhanced, such that the power efficiency curve constructed by the solid diamond data points is obviously greater than the power efficiency curve constructed by the hollow diamond data points.

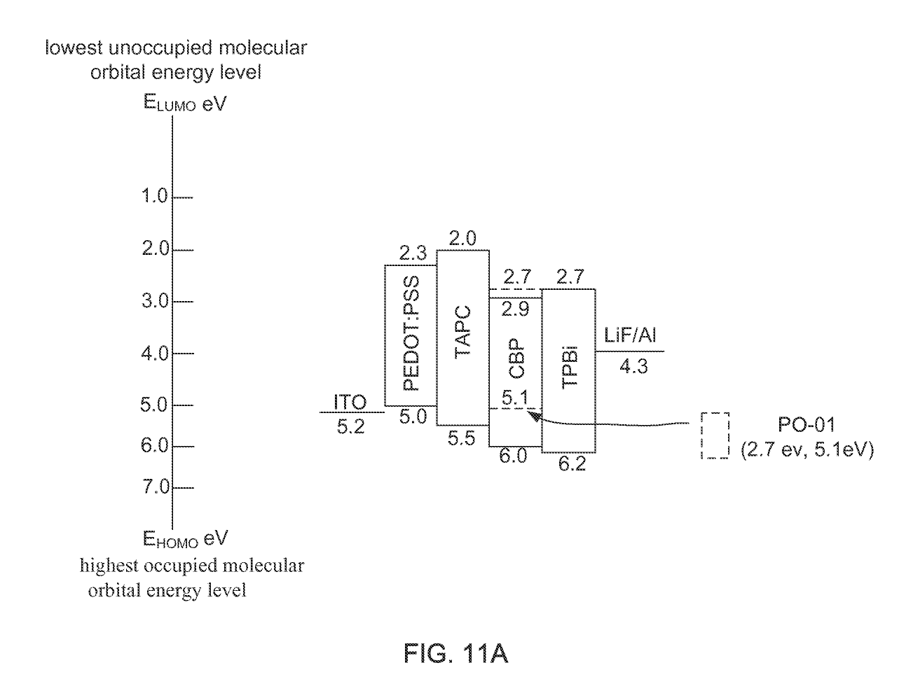

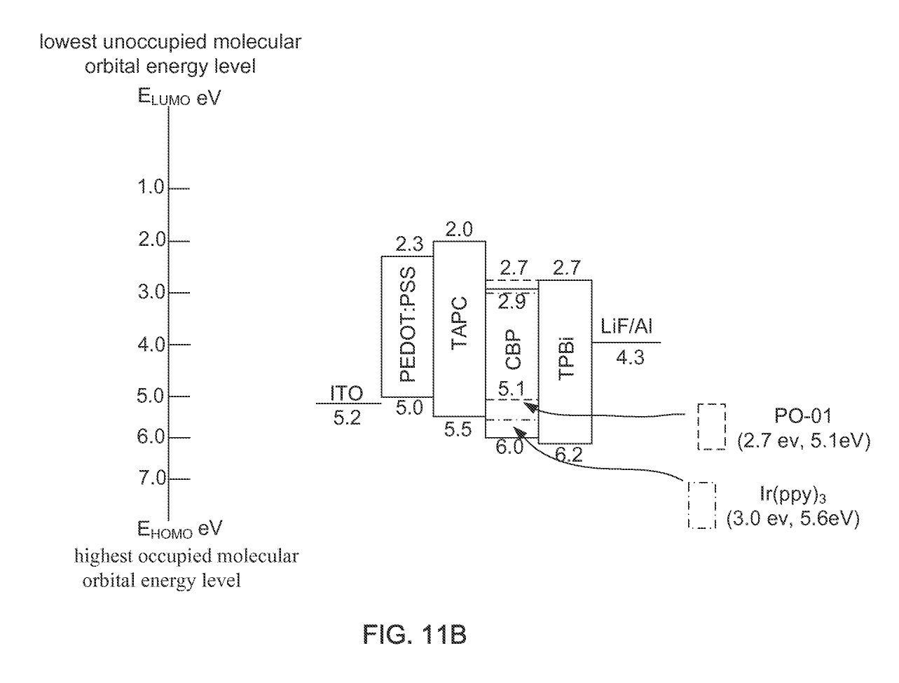

Therefore, according to the control OLED of FIG. 7A, the experiment OLED of FIG. 7B, and the experiment data of FIG. 10, it is able to know that the power efficiency of OLED is indeed enhanced by using TPBi, Ir(ppy)₃ and PO-01 as the host light-emitting layer, the first dye and the second dye, respectively. Continuously, please refer to FIG. 11A, it shows an energy band view of an organic light-emitting diode doped with a second dye; moreover, please simultaneously refer to FIG. 11B, it shows an energy band view of another organic light-emitting diode doped with a first dye and a second dye. The OLED framework of FIG. 11A is almost the same to above-mentioned OLED framework in FIG. 7A, but the only difference between the OLED of FIG. 11A and the OLED of FIG. 7A is that the host light-emitting layer in FIG. 11A is CBP. Similarly, the host light-emitting layer of OLED in FIG. 11B is also the CBP. In addition, the weight percentage (wt %) of second dye (PO-01) in the OLED of FIG. 11A is 15 wt %; and oppositely, the weight percentage of second dye (PO-01) in the OLED of FIG. 11B is 5.8 wt %, moreover the weight percentage of first dye (Ir(ppy)₃) in the OLED of FIG. 11B is 10 wt %.

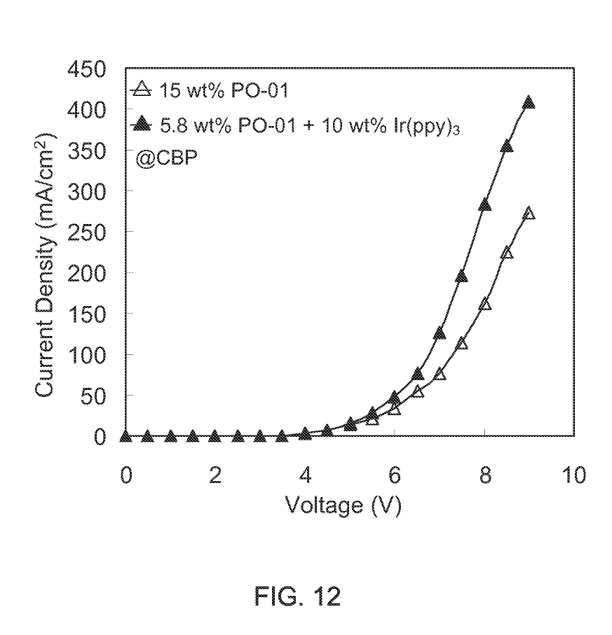

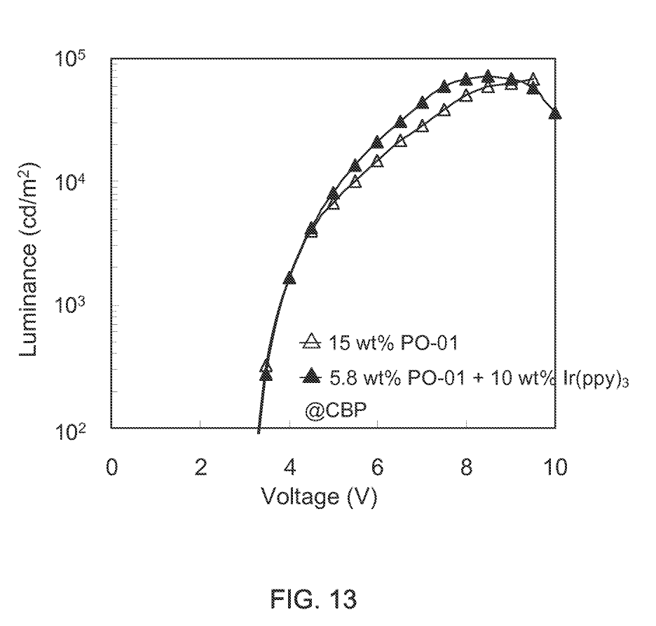

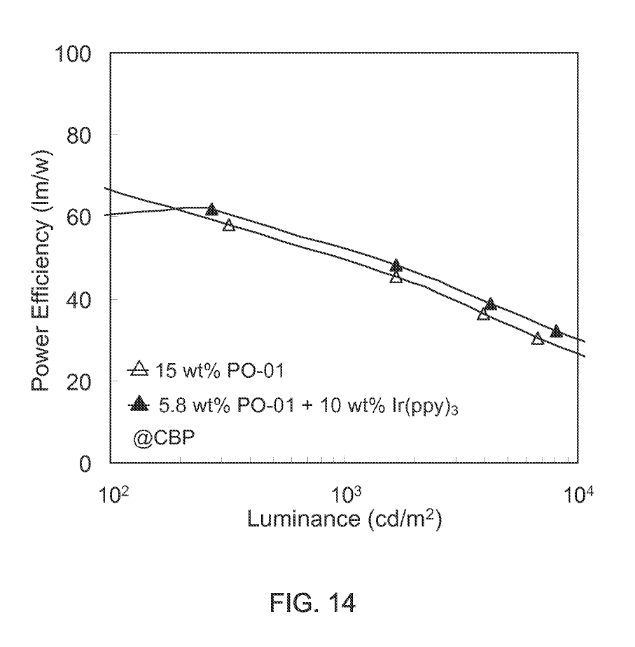

Please continuously refer to FIG. 12, FIG. 13 and FIG. 14, there are shown curve plots for the current density, the luminance and the power efficiency of two organic light-emitting diodes, respectively. In FIG. 12, the data points of hollow triangular represent the current density measured from the OLED of FIG. 11A, and the data points of solid triangular represent the current density measured from the OLED of FIG. 11B. As shown in FIG. 12, the current density curve constructed by the solid triangular data points is little higher than the current density curve constructed by the hollow triangular data points.

Besides, in FIG. 13, the data points of hollow triangular represent the luminance measured from the OLED of FIG. 11A, and the data points of solid triangular represent the luminance measured from the OLED of FIG. 11B. As shown in FIG. 13, the luminance measured from the OLED of FIG. 11B is little higher than the luminance measured from the OLED of FIG. 11A. Furthermore, in FIG. 14, the data points of hollow triangular represent the power efficiency measured from the OLED of FIG. 11A, and the data points of solid triangular represent the power efficiency measured from the OLED of FIG. 11B. As shown in FIG. 14, the power efficiency curve constructed by the solid triangular data points is little greater than the power efficiency curve constructed by the hollow triangular data points.

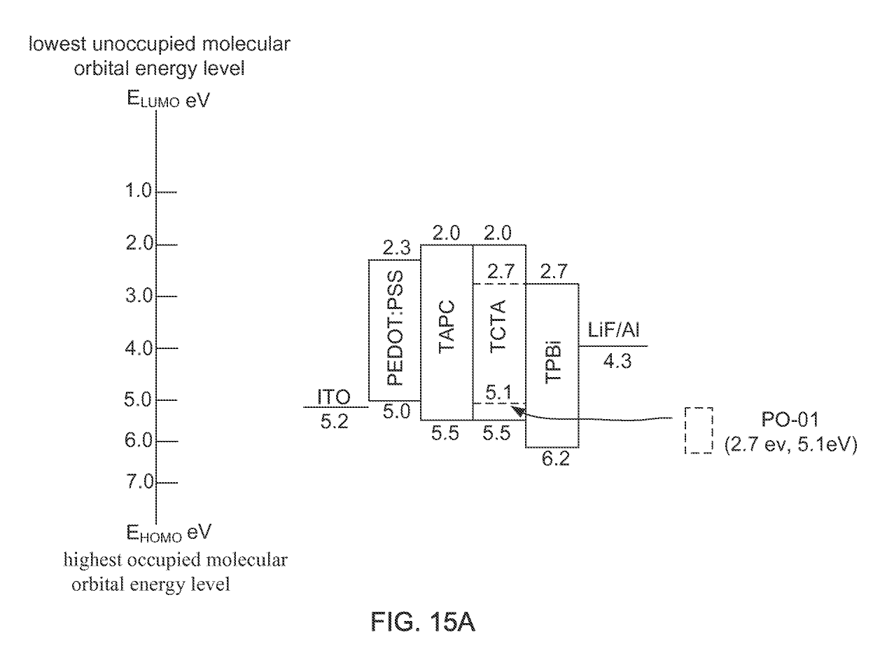

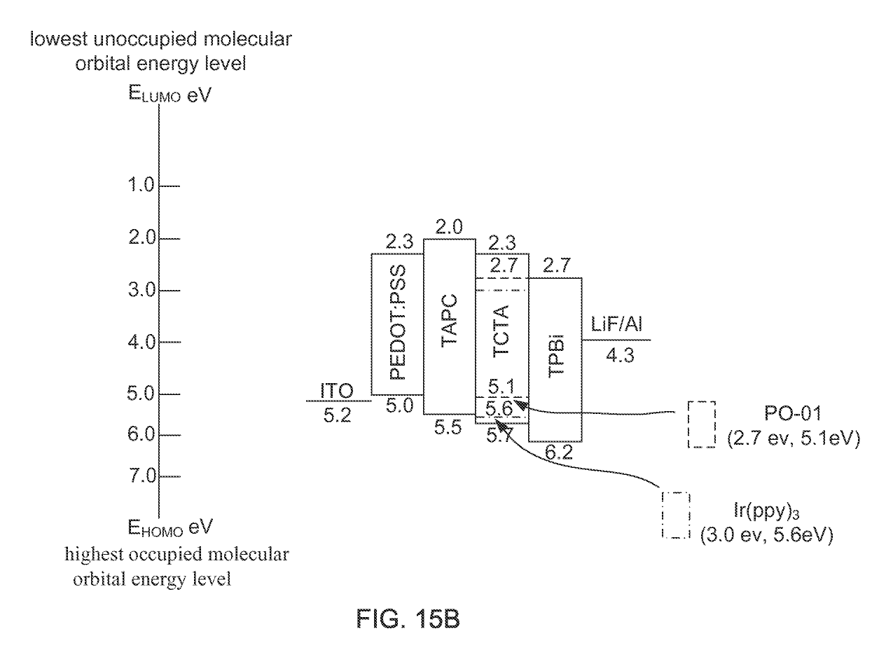

Therefore, according to the OLED of FIG. 11A, the OLED of FIG. 11B and the experiment data of FIG. 14, it is able to know that the power efficiency of OLED is indeed enhanced by using CBP, Ir(ppy)₃ and PO-01 as the host light-emitting layer, the first dye and the second dye, respectively. Continuously, please refer to FIG. 15A, it shows an energy band view of an organic light-emitting diode doped with a second dye; moreover, please simultaneously refer to FIG. 15B, it shows an energy band view of another organic light-emitting diode doped with a first dye and a second dye. The OLED framework of FIG. 15A is almost the same to above-mentioned OLED framework in FIG. 11A, but the only difference between the OLED of FIG. 15A and the OLED of FIG. 11A is that the host light-emitting layer in FIG. 15A is TCTA. Similarly, the host light-emitting layer of OLED in FIG. 15B is also the CBP. In addition, the weight percentage (wt %) of second dye (PO-01) in the OLED of FIG. 15A is 15 wt %; and oppositely, the weight percentage of second dye (PO-01) in the OLED of FIG. 15B is 5.8 wt %, moreover the weight percentage of first dye (Ir(ppy)₃) in the OLED of FIG. 14B is 10 wt %.

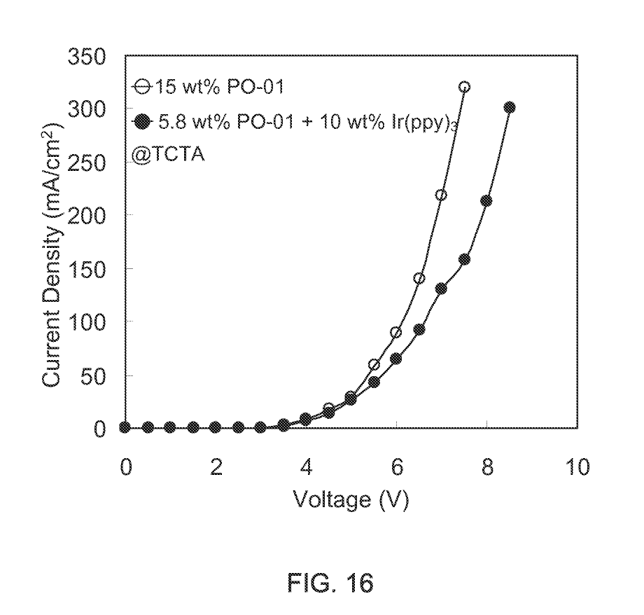

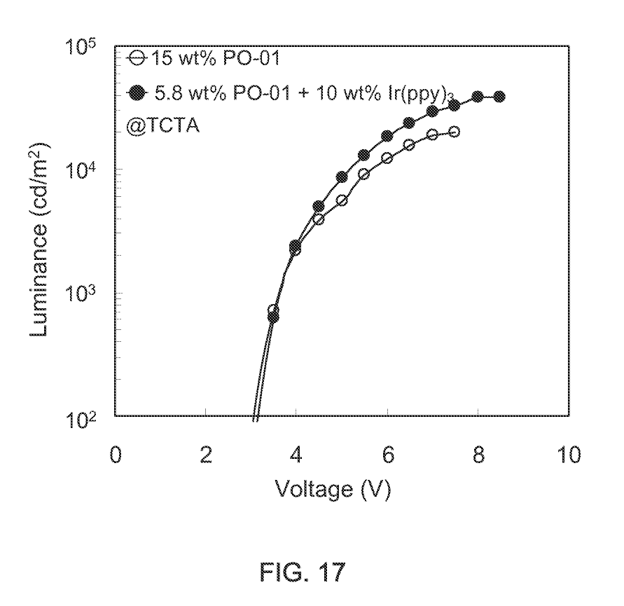

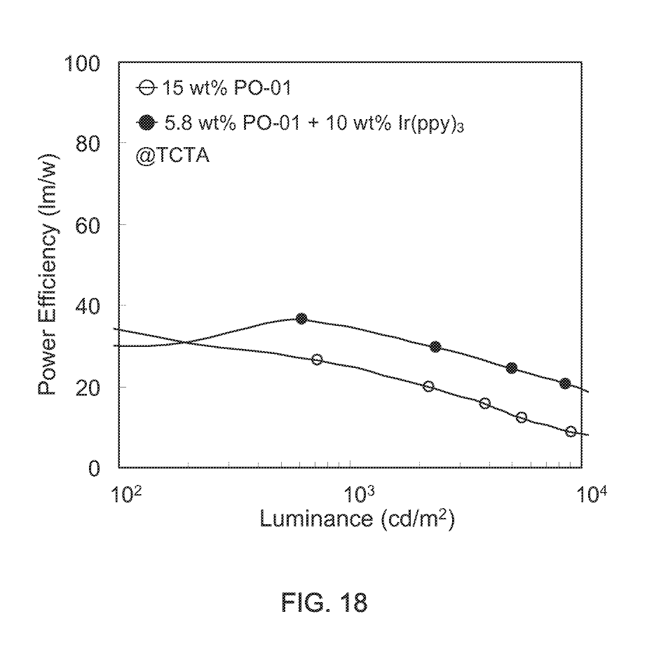

Please continuously refer to FIG. 16, FIG. 17 and FIG. 18, there are shown curve plots for the current density, the luminance and the power efficiency of two organic light-emitting diodes, respectively. In FIG. 16, the data points of hollow circular represent the current density measured from the OLED of FIG. 15A, and the data points of solid circular represent the current density measured from the OLED of FIG. 15B. As shown in FIG. 16, the current density curve constructed by the hollow circular data points is little higher than the current density curve constructed by the solid circular data points.

Besides, in FIG. 17, the data points of hollow circular represent the luminance measured from the OLED of FIG. 15A, and the data points of solid circular represent the luminance measured from the OLED of FIG. 15B. As shown in FIG. 17, the luminance measured from the OLED of FIG. 15B is little higher than the luminance measured from the OLED of FIG. 15A. Furthermore, in FIG. 18, the data points of hollow circular represent the power efficiency measured from the OLED of FIG. 15A, and the data points of solid circular represent the power efficiency measured from the OLED of FIG. 15B. As shown in FIG. 18, the power efficiency curve constructed by the solid circular data points is obviously greater than the power efficiency curve constructed by the hollow circular data points. Therefore, according to the OLED of FIG. 15A, the OLED of FIG. 15B and the experiment data of FIG. 18, it is able to know that the power efficiency of OLED is indeed enhanced by using TCTA, Ir(ppy)₃ and PO-01 as the host light-emitting layer, the first dye and the second dye, respectively.

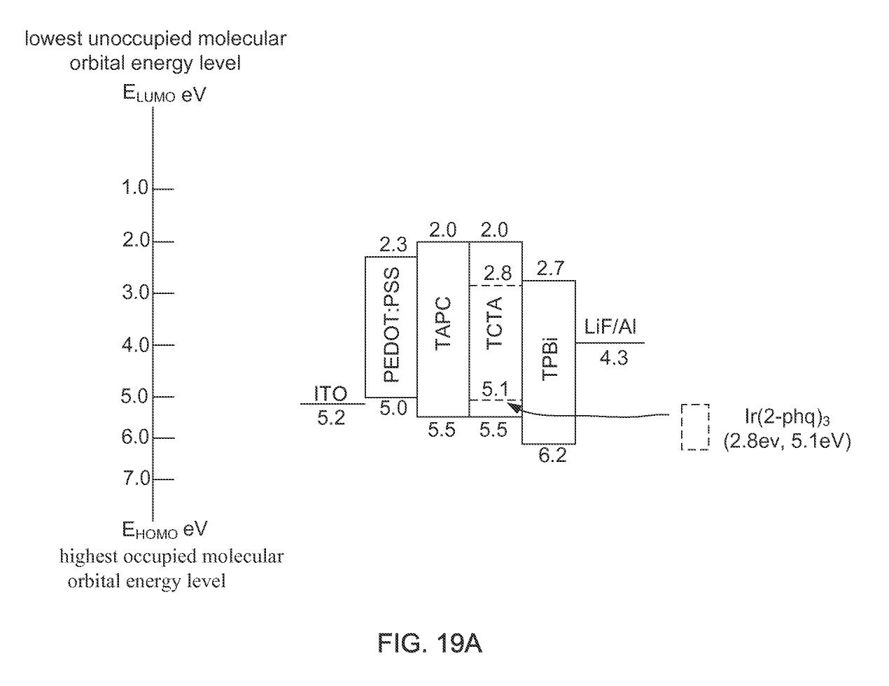

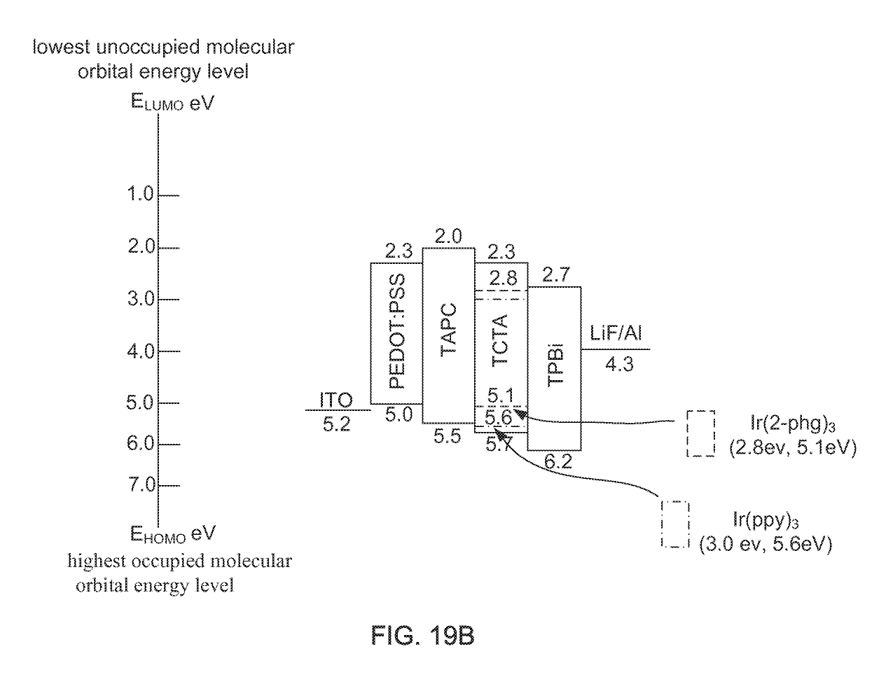

Moreover, in order to prove that the technology feature utilized in the organic light-emitting diode using bandgap matching dye as co-host proposed by the present invention can also be carried out when using Ir(ppy)₃ as the first dye and using Ir(2-phq)₃ as the second dye, the related experiment data will be shown in follows. Please refer to FIG. 19A, it shows an energy band view of an organic light-emitting diode doped with a second dye; moreover, please simultaneously refer to FIG. 19B, it shows an energy band view of another organic light-emitting diode doped with a first dye and a second dye. The OLED framework of FIG. 19A is almost the same to above-mentioned OLED framework in FIG. 15A, but the only difference between the OLED of FIG. 19A and the OLED of FIG. 15A is that the second dye in FIG. 19A is Ir(2-phq)₃; in addition, the OLED in FIG. 19B further includes the first dye of Ir(ppy)₃. Moreover, the weight percentage (wt %) of second dye Ir(2-phq)₃ in the OLED of FIG. 19A is 7.5 wt %; and oppositely, the weight percentage of second dye Ir(2-phq)₃ in the OLED of FIG. 19B is 7.5 wt %, and the weight percentage of first dye (Ir(ppy)₃) in the OLED of FIG. 19B is 7.5 wt %.

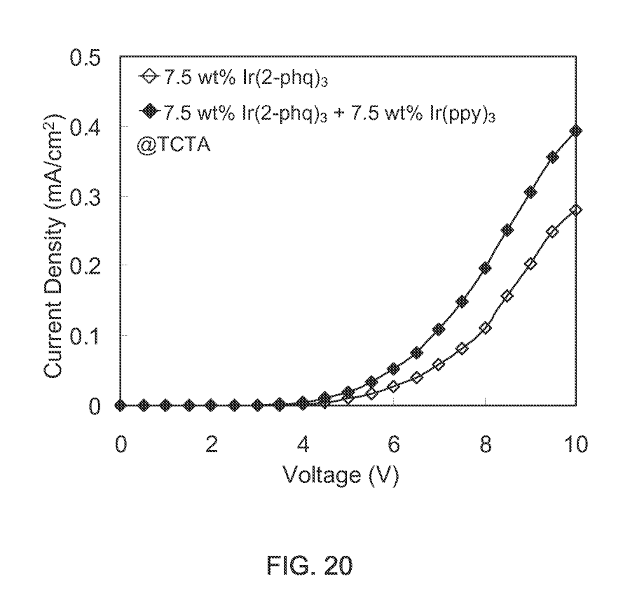

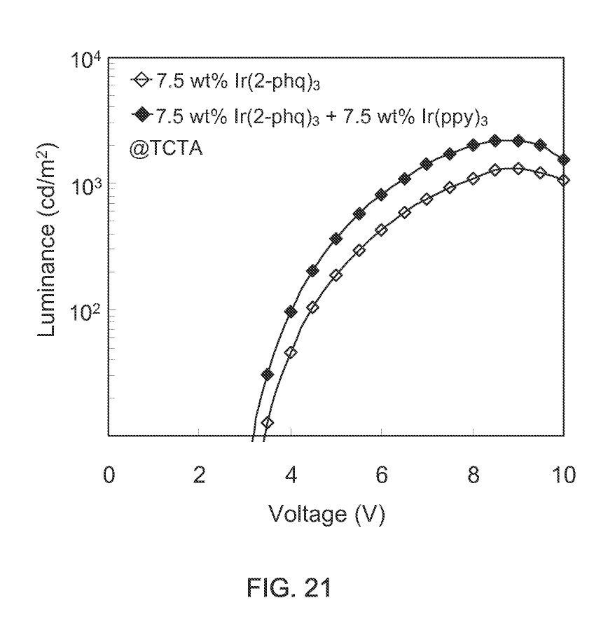

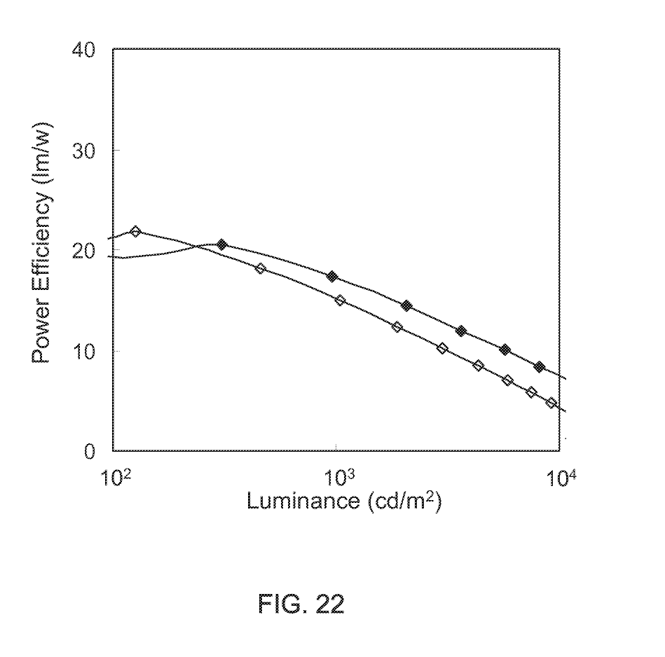

Please continuously refer to FIG. 20, FIG. 21 and FIG. 22, there are shown curve plots for the current density, the luminance and the power efficiency of two organic light-emitting diodes, respectively. In FIG. 20, the data points of hollow diamond represent the current density measured from the OLED of FIG. 19A, and the data points of solid diamond represent the current density measured from the OLED of FIG. 19B. As shown in FIG. 20, the current density curve constructed by the solid diamond data points is little higher than the current density curve constructed by the hollow diamond data points.

Besides, in FIG. 21, the data points of hollow diamond represent the luminance measured from the OLED of FIG. 19A, and the data points of solid diamond represent the luminance measured from the OLED of FIG. 19B. As shown in FIG. 21, the luminance measured from the OLED of FIG. 19B is greater than the luminance measured from the OLED of FIG. 19A. Furthermore, in FIG. 22, the data points of hollow diamond represent the power efficiency measured from the OLED of FIG. 19A, and the data points of solid diamond represent the power efficiency measured from the OLED of FIG. 19B. As shown in FIG. 22, the power efficiency curve constructed by the solid diamond data points is greater than the power efficiency curve constructed by the hollow diamond data points. Therefore, according to the OLED of FIG. 19A, the OLED of FIG. 19B and the experiment data of FIG. 22, it is able to know that the power efficiency of OLED is indeed enhanced by using TCTA, Ir(ppy)₃ and Ir(2-phq)₃ as the host light-emitting layer, the first dye and the second dye, respectively.

Thus, through the descriptions, the organic light-emitting diode using bandgap matching dye as co-host of the present invention has been completely introduced and disclosed; Moreover, the practicability and the technology feature have also been proven by various experiment data. So that, in summary, the present invention has the following advantages:

In the present invention, it properly selects a first dye and a second dye to dope them into the host light-emitting layer, so as to make the host energy gap of the host light-emitting layer greater than the energy gap of the first dye and the energy gap of the first dye greater than the energy gap of the second dye; Therefore, the first dye can be a co-host light-emitting layer opposite to the host light-emitting layer, and the energy of the first dye can be effectively conducted to the second dye, such that the luminous efficiency of the light emitted by the second dye through the host light-emitting layer is largely enhanced.

The above description is made on embodiments of the present invention. However, the embodiments are not intended to limit scope of the present invention, and all equivalent implementations or alterations within the spirit of the present invention still fall within the scope of the present invention.

What is claimed is:

1. An organic light-emitting diode using bandgap matching dye as co-host, comprising:
a first conductive layer;
a hole injection layer, being formed on the first conductive layer;
a hole transport layer, being formed on the hole injection layer;
a host light-emitting layer, being formed on the hole transport layer and having a host energy gap;
a first dye, being doped in the host light-emitting layer;
a second dye, being doped in the host light-emitting layer;
an electron transport layer, being formed on the host light-emitting layer;
an electron injection layer, being formed on the electron transport layer; and
a second conductive layer, being formed on the electron injection layer;
wherein the host energy gap of the host light-emitting layer is greater than the energy gap of the first dye, and the energy gap of the first dye is greater than the energy gap of the second dye, and the energy of the first dye can be effectively conducted to the second dye, such that the luminous efficiency of the light emitted is largely enhanced.

2. The organic light-emitting diode using bandgap matching dye as co-host of claim 1, wherein the first conductive layer is an indium tin oxide (ITO) for being as an anode, and the material of the second conductive layer being aluminum, used as a cathode.

3. The organic light-emitting diode using bandgap matching dye as co-host of claim 1, wherein the material of the hole injection layer is poly(3,4-ethylene-dioxythiophene):poly-(styrenesulfonate) (PEDOT:PSS), the material of the hole transport layer being (1,1-bis{4-[di(p-tolyl)amino]-phenyl}cyclohexane) (TAPC), the material of the electron injection layer being LiF, and the material of the electron transport layer being 1,3,5-tris(N-phenylbenzimidazol-2-yl)benzene (TPBi).

4. The organic light-emitting diode using bandgap matching dye as co-host of claim 1, wherein the first dye is tris(2-phenylpyridine)iridium (Ir(ppy)₃).

5. The organic light-emitting diode using bandgap matching dye as co-host of claim 1, wherein the second dye is selected from the group consisting of: iridium(III)bis(4-phenylthieno [3,2-c]pyridinato-N,C2) acetylacetonate (PO-01) and tris(2-phenylquinoline)iridium(III) (Ir(2-phq)₃).

6. The organic light-emitting diode using bandgap matching dye as co-host of claim 1, wherein the material of the host light-emitting layer is selected from the group consisting of: 1,3,5-tris(N-phenylbenzimidazol-2-yl)benzene (TPBi), 4,4′-Bis(9H-carbazol-9-yl)biphenyl (CBP) and 4,4′,4″-Tri(9-carbazoyl)triphenylamine (TCTA).

7. The organic light-emitting diode using bandgap matching dye as co-host of claim 1, wherein the weight percentage (wt %) of the first dye in the host light-emitting diode is ranged from 5 wt % to 15 wt %.

8. The organic light-emitting diode using bandgap matching dye as co-host of claim 1, wherein the weight percentage (wt %) of the second dye in the host light-emitting diode is ranged from 5 wt % to 15 wt %.
